(19) United States
(12) Patent Application Publication
(10) Pub. No.: US 2007/0105320 A1
(43) Pub. Date: May 10, 2007

(54) Method and Structure of Multi-Surface Transistor Device

(75) Inventor: Xiao (Charles) Yang, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Xiao ("Charles") Yang

(21) Appl. No.: 11/469,329

(22) Filed: Aug. 31, 2006

Related U.S. Application Data
(60) Provisional application No. 60/713,278, filed on Aug. 31, 2005.

(51) Int. Cl. H01L 21/336; H01L 29/76

(52) U.S. Cl. 438/268; 257/288

(57) ABSTRACT

A double gated MOS transistor structure and method of manufacture. Fabricating transistor devices on both top and bottom surfaces of the silicon layer creates vertical double gate transistor devices. The presented double gate transistor devices do not require alignment of the top and bottom gates. In addition to double gate transistor devices, it is possible to fabricate two layers of independent transistor devices using a similar process. The two layers transistor devices can be interconnected by short VIAs thru the thin silicon layer.

### CROSS-REFERENCES TO RELATED APPLICATIONS

This application claims priority to U.S. Provisional Application No. 60/713,278 filed Aug. 31, 2005 and incorporated by reference herein

### BACKGROUND OF THE INVENTION

According to the present invention, techniques for fabricating integrated circuits on two surfaces of a silicon substrate are provided. More particularly, the invention includes a method and structure for fabricating single gate and dual gate transistor devices using both top and bottom surfaces of a silicon substrate. Merely by way of example, the invention has been applied to fabricating transistors on two surfaces of a common substrate. But it would be recognized that the invention has a much broader range of applicability.

The transistor is the building block of integrated circuits in modern microchips. The performance of the chip depends largely on the ability of its millions of transistors to switch on and off quickly and completely, and to require the least amount of energy to do so. Transistors usually have a source, a gate, and a drain. The gate controls the electrical flow through the transistor. Passing electricity through the gate moves current from the source to the drain, completing the circuit. Currently, a single gate is equidistant from the source and drain, positioned above them. But as chips continue to shrink, single-gate transistors will experience increased electron leakage, higher energy needs, and worsened electrical flow. It becomes more difficult for a single gate to effectively control switching.

Traditional Integrated Circuit devices are fabricated on a surface of a silicon substrate, i.e. planar devices. It is desirable to fabricate transistor devices on dual surfaces of a silicon substrate to create double gated transistor devices. The dual surfaces architecture can also be used to fabricate functional integrated circuits on each surface with short interconnects between them. As a result, the dual surfaces architecture may improve density and performance of IC devices. Unfortunately, dual surfaces are often difficult to manufacture in a cost effective manner. These and other limitations of double gated devices are described through out the present specification.

From the above, it is seen that techniques for manufacturing double gated devices are highly desired.

### BRIEF SUMMARY OF THE INVENTION

According to the present invention, techniques for fabricating a double gated structure are provided. More particularly, the present invention provides a method and device for double gated structures using a self aligned process. The self aligned process can be used with suitable techniques such as etching, patterning, and layer transfer processes such as SmartCut™ by Soitec SA to create a thin layer of silicon material consists of a top and bottom surfaces. According to one embodiment of the present invention, a starting substrate is a Silicon On Insulator (SOI) substrate or other suitable substrate. First, a gate dielectric layer is form on the top surface of the SOI substrate, typically by thermal oxidation. A layer of Polycrystalline silicon is then deposited and subsequently fabricated to become the bottom gate for the final device. A dielectric layer such as HDP oxide or nitride is deposited on top of the poly silicon layer followed by a Chemical Mechanical Polish (CMP) process to further planarize and smoothen the surface. The SOI substrate is then joined to a handle substrate by a permanent bonding method such as fusion or covalent bonding. After the bonding step, the bulk of the SOI wafer is removed by a thinning method possibly involving grinding followed by a wet or dry etch stop on the BOX. The thinning process expose the other silicon surface of the SOI for front device processing. A standard IC process is then applied to form double-gated transistor devices. Unlike typical single gate MOS devices, the double gate transistors in present invention have two inversion layers of electrons or holes which doubles the current with a given gate voltage. Furthermore, the presented double gate transistor devices do not require alignment of the top and bottom gates, which eliminates the device performance variation due to misalignment. In addition to double gate transistor devices, it is possible to fabricate two layers of independent transistor devices using a similar process. The two layers transistor devices can be interconnected by short VIAs thru the thin silicon layer. Dual layer structure increases transistor density and performance by integrating different functionalities thru short local VIAs. Additionally, the SOI wafer can be made using other techniques such as SIMOX or other suitable techniques.

In an alternative specific embodiment, the present invention provides a multi-surface transistor device, e.g., double gated device. The device has a substrate member (e.g., silicon) comprising a surface region. The device has an insulating layer overlying the surface region of the substrate member and a first gate structure overlying the insulating layer. The device has a first gate insulating layer overlying the first gate structure. The device has an active region overlying the first gate insulating layer. In a specific embodiment, the active region has a source region, a channel region, and a drain region. In a specific embodiment, the device has a second gate insulating layer overlying at least the channel region of the active region. The device has a patterned second gate structure overlying the channel region of the active region. The patterned gate structure has a first edge region and a second edge region. A first sidewall spacer is formed on the first edge region. A second sidewall spacer is formed on the second edge region. In a specific embodiment, the device has a trench isolation structure provided to form a boundary for the active region and provided to form the first gate structure and isolate the first gate structure from at least a second cell region.

In yet an alternative specific embodiment, the present invention provides a method for forming double gated MOS transistor device. The method includes providing a substrate member comprising a surface region and forming an insulating layer overlying the surface region of the substrate member. The method includes forming a first gate layer overlying the insulating layer. The method includes forming a first gate insulating layer overlying the first gate layer. The method includes forming an active region overlying the first gate insulating layer. In a preferred embodiment, the active region has a source region, a channel region, and a drain region. The method includes forming a second gate insulating layer overlying at least the channel region of the active region and forming a second gate layer overlying the second gate insulating layer. The method includes patterning the second gate layer to form a second gate structure overlying the channel region of the active region. The second gate structure has a first edge region and a second edge region. In a specific embodiment, the method includes providing a first sidewall spacer formed on the first edge region and a second sidewall spacer formed on the second edge region. The method includes forming a trench isolation structure to provide an isolation region formed within a vicinity of a boundary of the active region provided by the trench isolation structure and simultaneously during a portion of the forming of the trench isolation structure forming a first gate structure from the first gate layer to isolate the first gate structure from at least an adjacent cell region. In a preferred embodiment, the first gate structure is self aligned to the active region, including the channel region. That is, the first gate structure can have a lateral dimension that is substantially the same as the lateral dimension of the active region.

Many benefits are achieved by way of the present invention over conventional techniques. For example, the present technique provides an easy to use process that relies upon conventional technology. In some embodiments, the method provides higher device yields in dies per wafer using the self aligned process. Additionally, the method provides a process that is compatible with conventional process technology without substantial modifications to conventional equipment and processes. In a preferred embodiment, the present method provides a double gated process that uses a self aligned technique.

Depending upon the embodiment, one or more of these benefits may be achieved. These and other benefits will be described in more throughout the present specification and more particularly below.

### BRIEF DESCRIPTION OF THE DRAWINGS AND DETAILED DESCRIPTION OF THE INVENTION

According to the present invention, techniques for fabricating integrated circuits on two surfaces of a silicon substrate are provided. More particularly, the invention includes a method and structure for fabricating single gate and dual gate transistor devices using both top and bottom surfaces of a silicon substrate. Merely by way of example, the invention has been applied to fabricating transistors on two surfaces of a common substrate. But it would be recognized that the invention has a much broader range of applicability.

FIG. 1 is a simplified cross-sectional diagram illustrating components of a dual gate MOSFET device according to one embodiment of the present invention. The following diagrams are merely examples, which should not unduly limit the scope of the claims herein. One of ordinary skill in the art would recognize many variations, alternatives, and modifications.

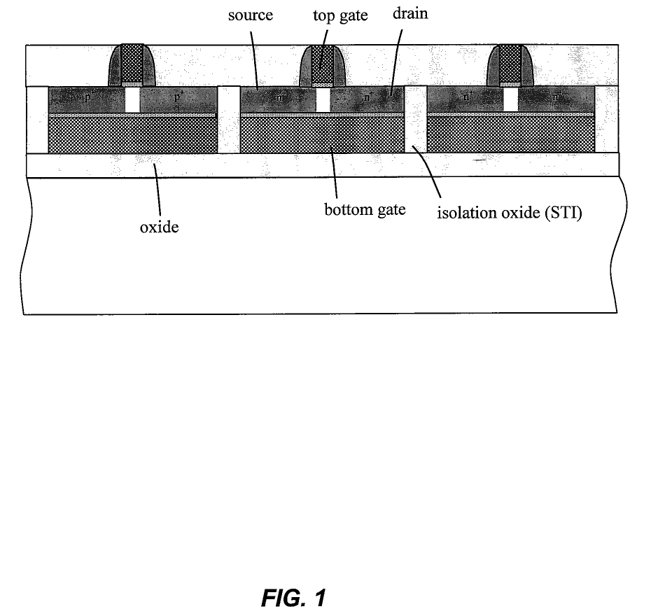

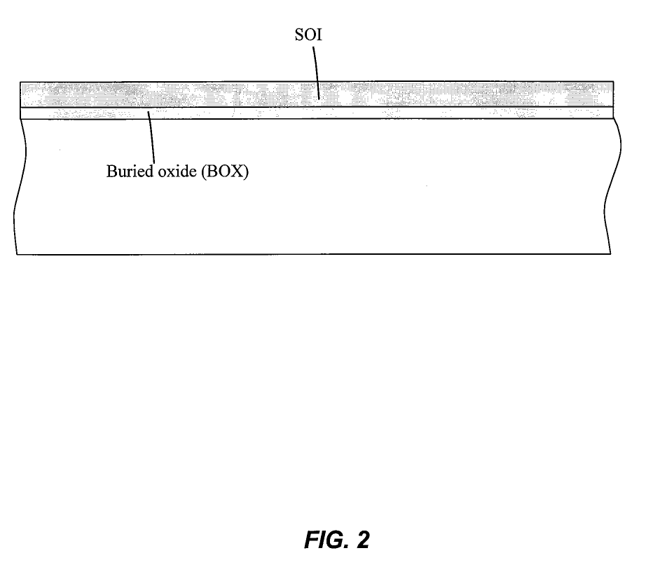

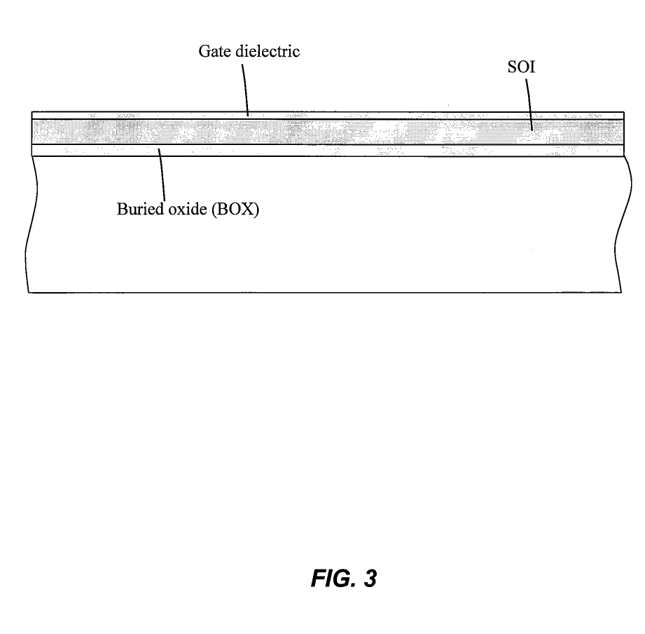

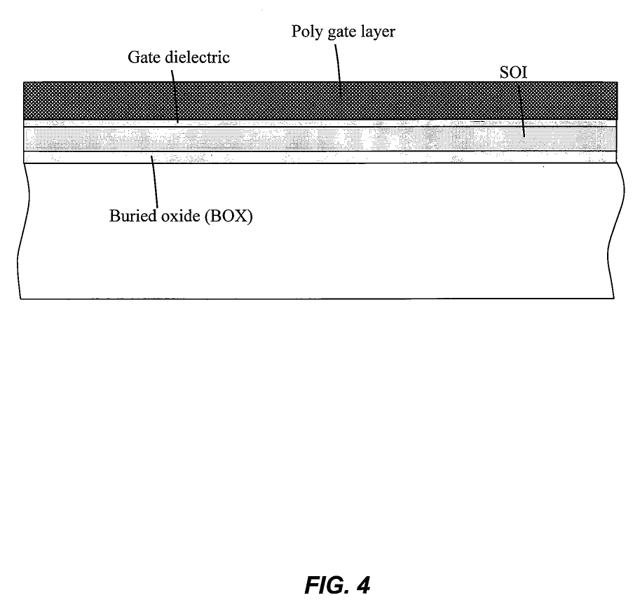

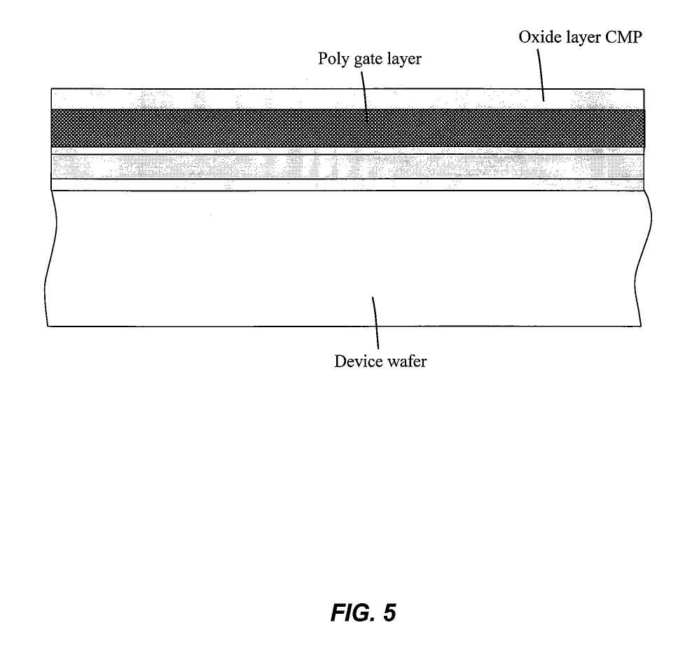

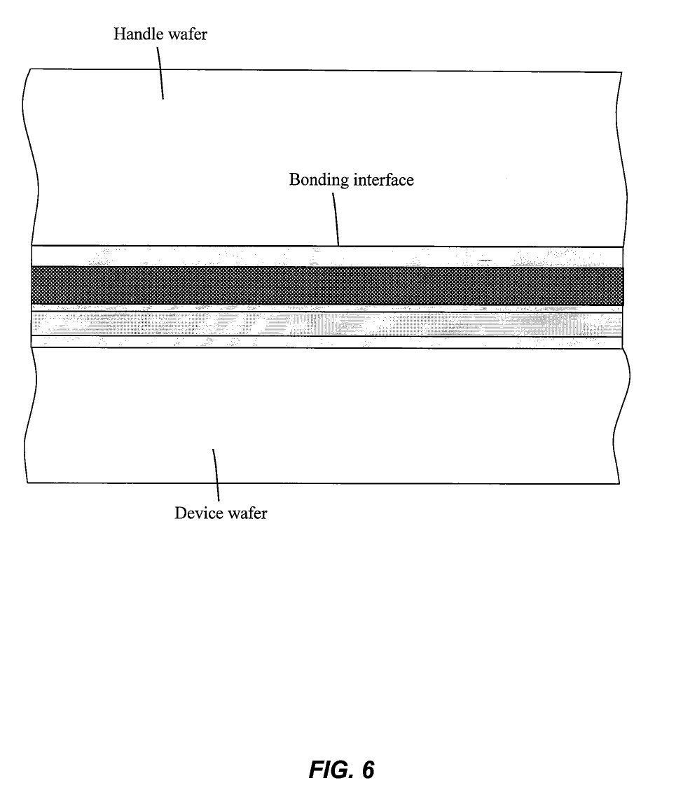

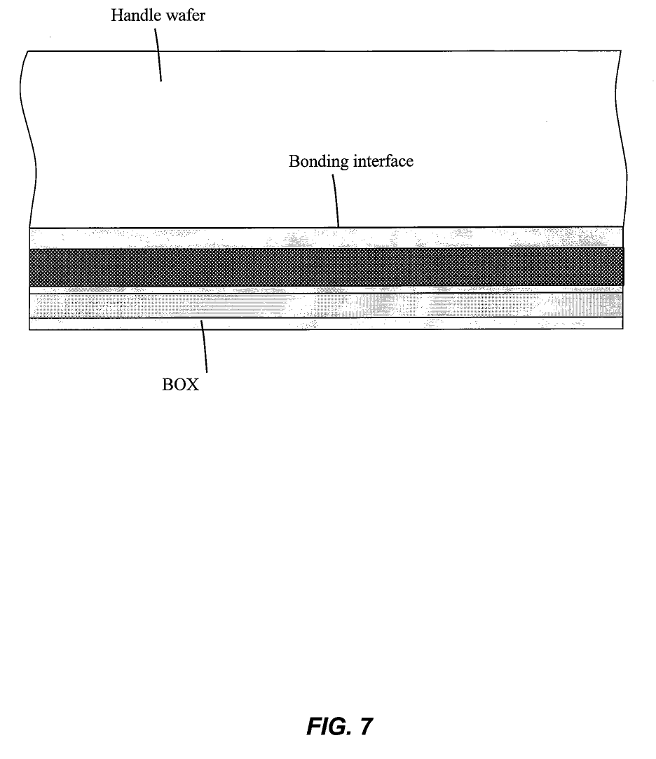

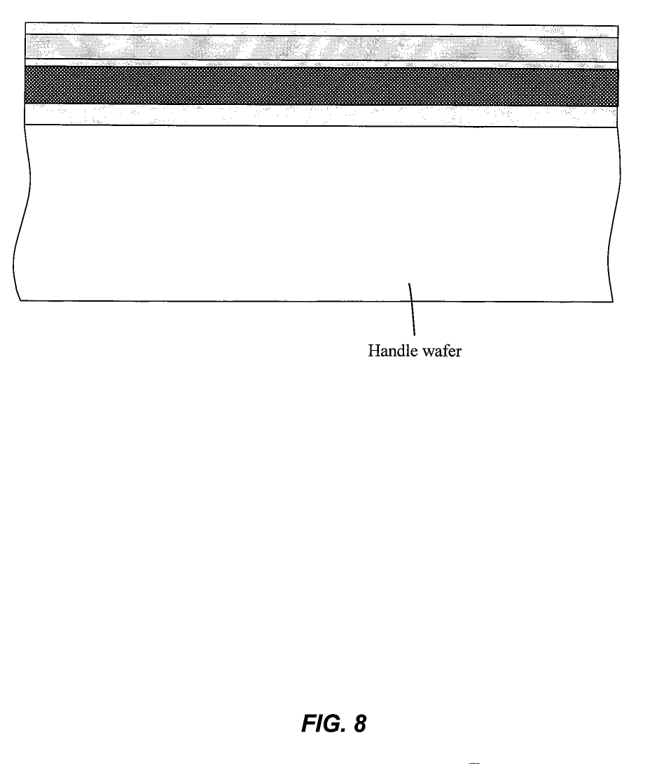

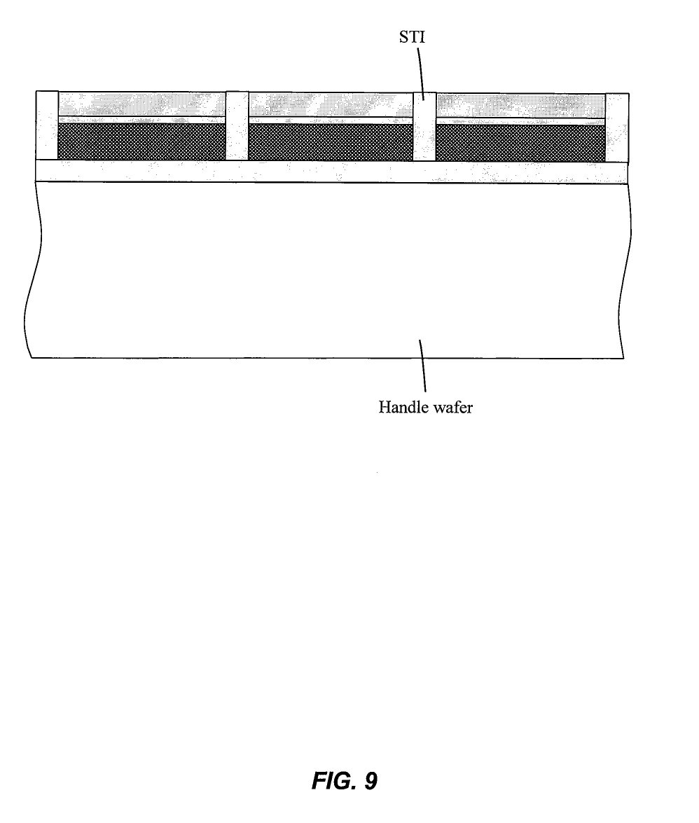

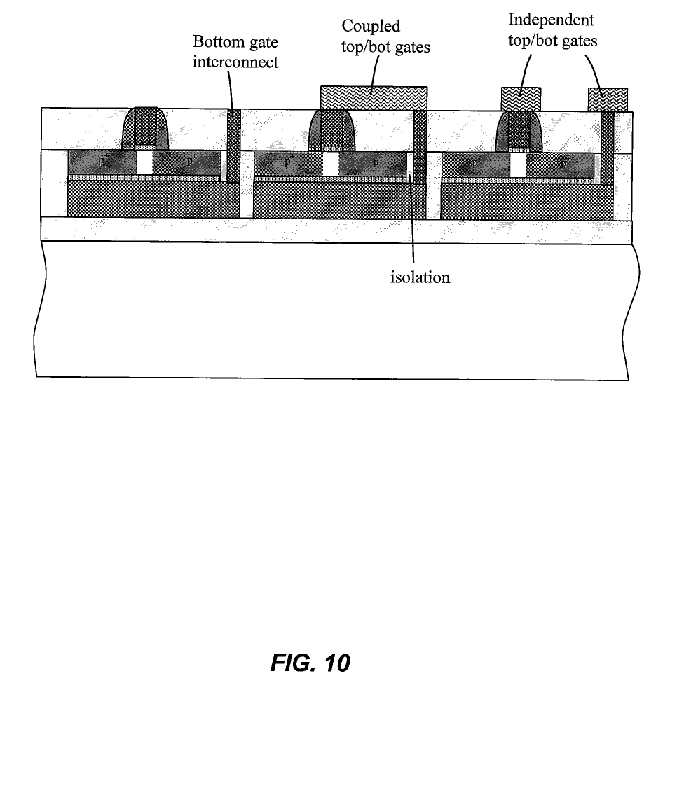

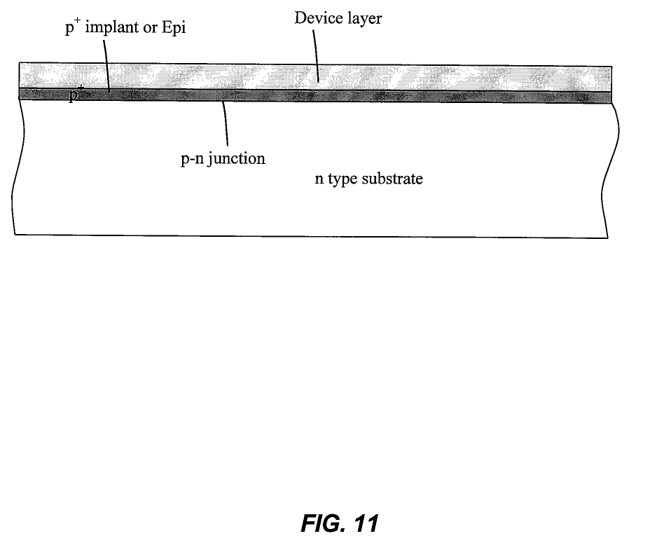

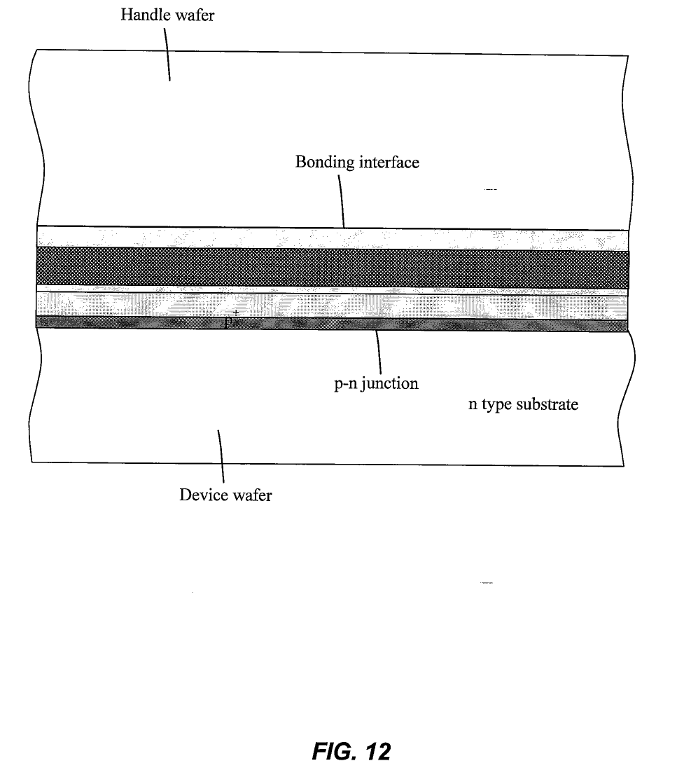

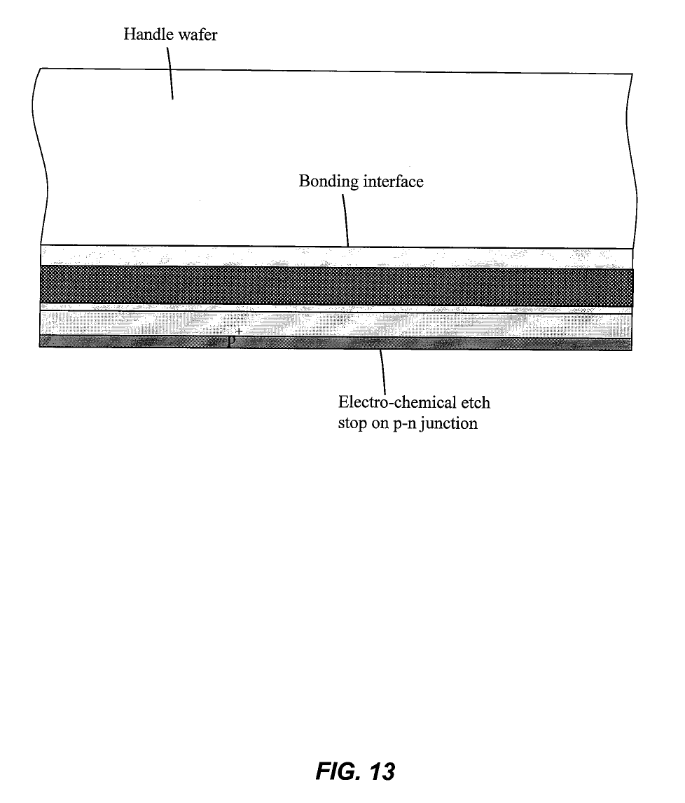

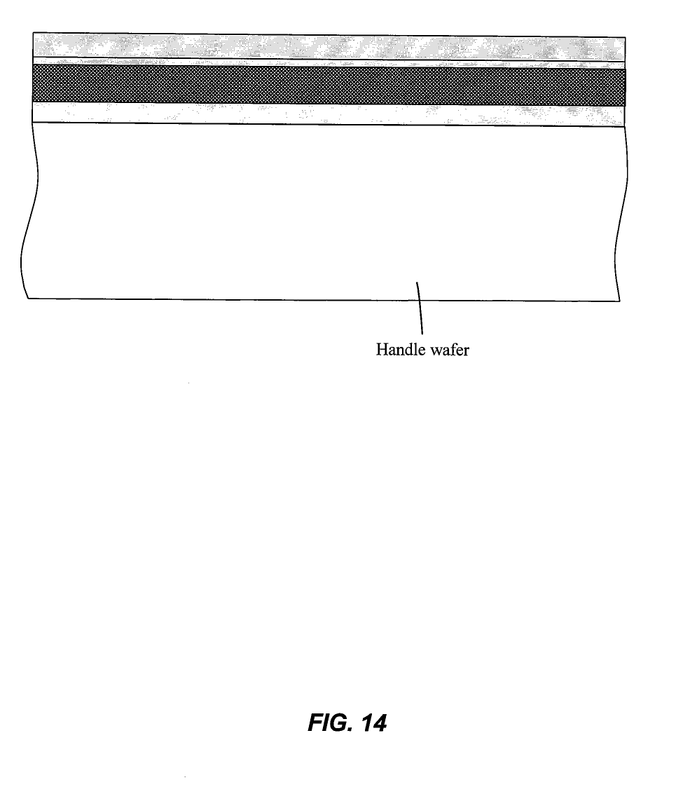

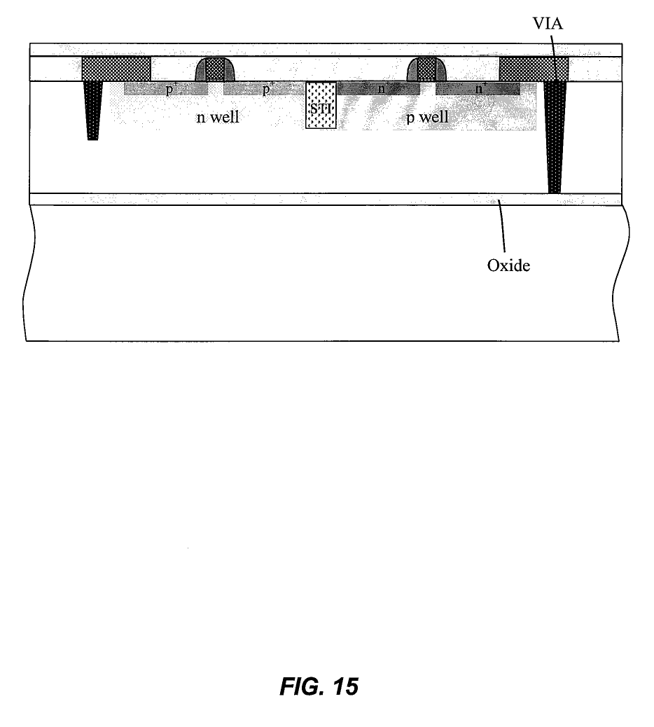

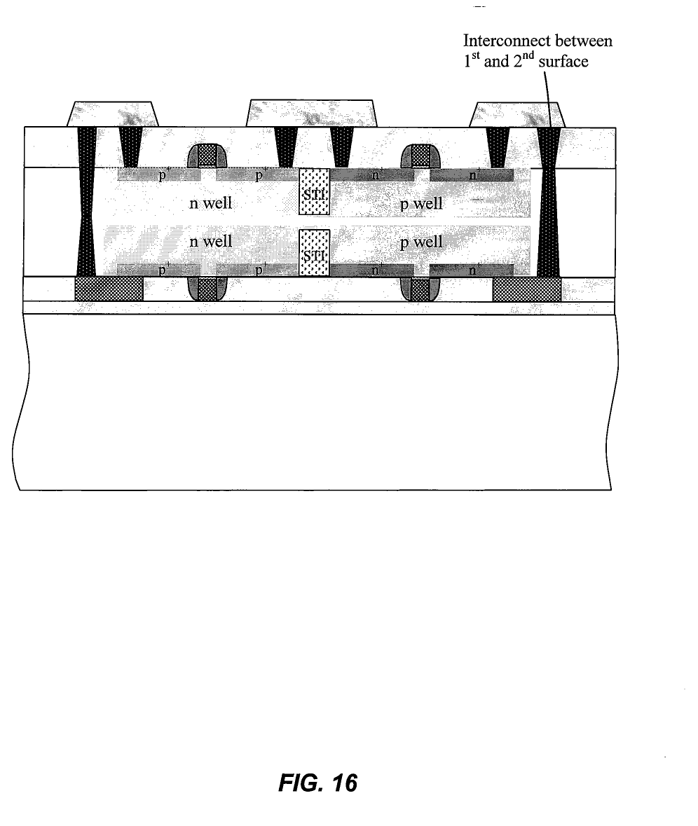

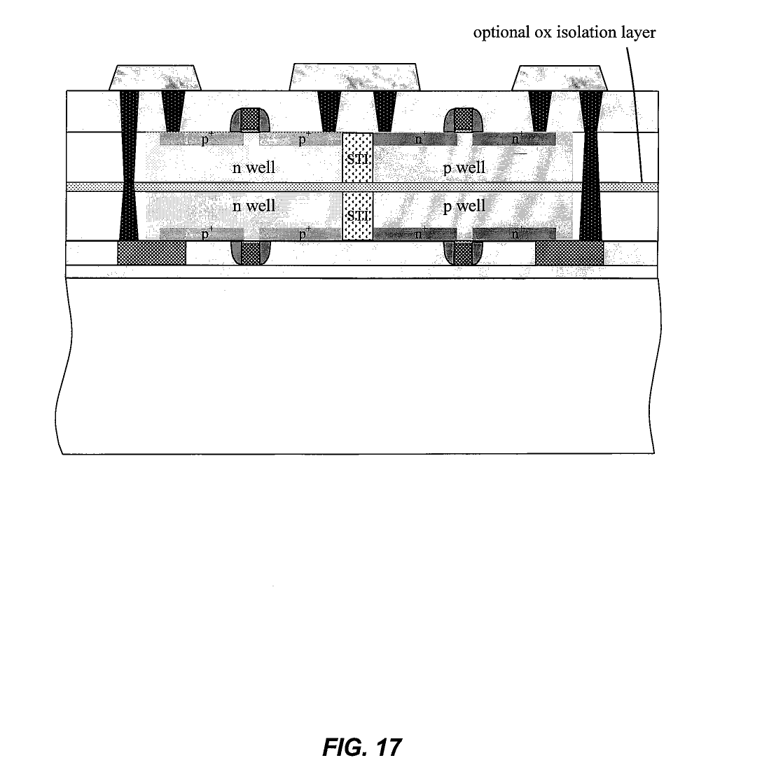

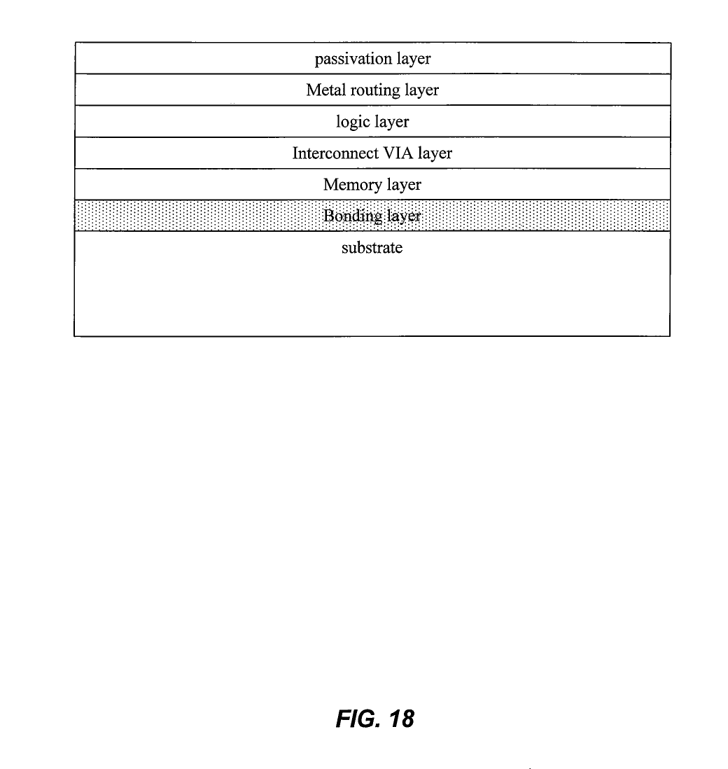

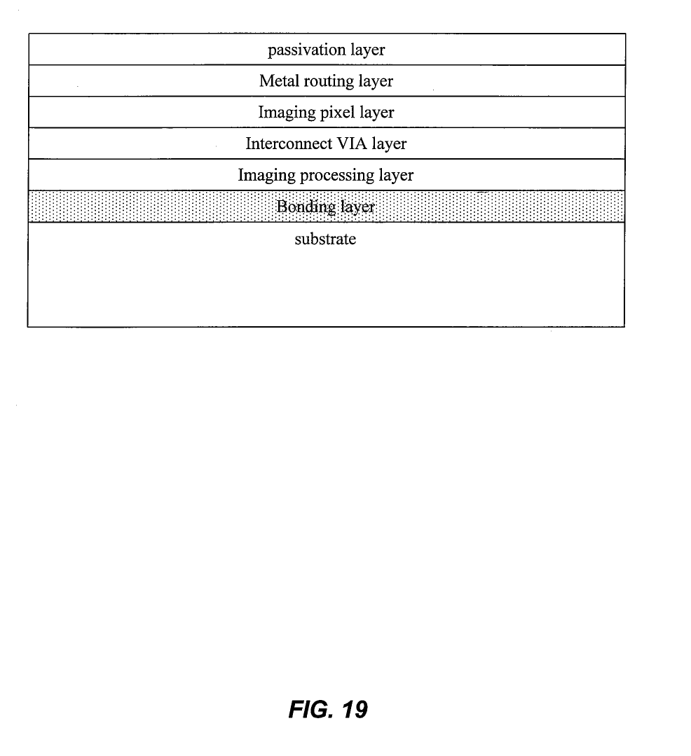

As illustrated, the top gate is a standard gate structure that is between a source and drain. The bottom gate, however, is extended to the cover both the source and drain regions. The top and bottom gates can be either connected controlled by a common voltage or electrically isolated controlled by separated voltages independently. The source and drain regions can be either partially or fully depleted depending on applications. A shallow trench isolation (STI) typically oxide is formed to electrically isolate adjacent transistors. A oxide layer electrically isolates the transistors from each other as well as from the substrate. Above the top gates, standard Aluminum or Copper interconnect methods are applied to build the remaining structure of the device.

In an specific embodiment, the present invention provides a method for forming double gated MOS transistor device as outlined below.
1. Provide a substrate member comprising a surface region;
2. Form an insulating layer overlying the surface region of the substrate member;
3. Form a first gate layer overlying the insulating layer;
4. Form a first gate insulating layer overlying the first gate layer;
5. Form an active region overlying the first gate insulating layer;
6. Form a second gate insulating layer overlying at least the channel region of the active region;
7. Form a second gate layer overlying the second gate insulating layer;
8. Pattern the second gate layer to form a second gate structure overlying the channel region of the active region;
9. Provide a first sidewall spacer formed on the first edge region and a second sidewall spacer formed on the second edge region of the second gate structure; and

10. Form a trench isolation structure to provide an isolation region formed within a vicinity of a boundary of the active region provided by the trench isolation structure and simultaneously, during a portion of the forming of the trench isolation structure, forming a first gate structure from the first gate layer to isolate the first gate structure from at least an adjacent cell region (In a preferred embodiment, the first gate structure is self aligned to the active region, including the channel region. That is, the first gate structure can have a lateral dimension that is substantially the same as the lateral dimension of the active region.

The above sequence of steps provides a method according to an embodiment of the present invention. As shown, the method uses a combination of steps including a way of forming a double gated structure using a self-aligned process for integrated circuits. Other alternatives can also be provided where steps are added, one or more steps are removed, or one or more steps are provided in a different sequence without departing from the scope of the claims herein. Further details of the present method can be found throughout the present specification and more particularly below.

FIGS. 2-10 are simplified cross-sectional diagrams illustrating a process flow of fabricating dual gate transistors on two surfaces of a common substrate according to an embodiment of the present invention. As illustrated in FIG. 2, a starting substrate maybe a Silicon On Insulator (SOI) substrate. A gate dielectric layer is form, typically by thermal oxidation as shown in FIG. 3. A layer of Polycrystalline silicon is then deposited as depicted in FIG. 4. The Poly silicon is subsequently fabricated to become the bottom gate. As illustrated in FIG. 5, a dielectric layer such as HDP oxide or nitride is deposited on top of the poly silicon. A Chemical Mechanical Polish (CMP) process can be applied to further planarize and smoothen the surface. At this step, this wafer is denoted as the device wafer.

FIG. 6 is a simplified diagram illustrating a process of joining the device wafer to a handle substrate. Although common permanent bonding methods such as eutectic, glass frit, BCB, etc., methods such as SOG, fusion or covalent bonding are suitable due to subsequent high temperature process. The handle substrate can be a silicon wafer but not limited to silicon, it can also be a glass wafer, or germanium or others. Since there's no feature on both substrates, no alignment is needed, which eliminate a variable on device performance. That is, the process is self aligned in a preferred embodiment. Merely by way of example, a surface activation by either plasma or wet on both substrates is applied followed by a room temperature covalent bonding process.

After the bonding step, the bulk of the device wafer is removed by methods such as grinding, followed by a wet or dry etch as showed stop on the BOX as illustrated in FIG. 7. The substrate is then ready for front device processing as shown in FIG. 8. The BOX ox can be used as a masking layer. As illustrated in FIG. 9, shallow isolation trenches are formed. A standard process is applied to form the remaining structure of the device as shown in FIG. 10. The top and bottom gates can be either electrically connected or isolated depending applications.

This sequence of fabricating dual gate transistor can be reversed in one embodiment, i.e. the shorter gate is at the bottom and the wider gate is at the top.

SOI is a high cost substrate. As illustrated from FIG. 11-14, an alternative low cost method can be used to fabricate similar devices without using SOI. As depicted in FIG. 11, the starting substrate is n type wafer with an implanted p+ layer instead of SOI. The top device layer can be the native layer after the implant or at a desired thickness using epi. Similar process is applied to fabricate the device wafer as shown in FIG. 12. Same bonding methods can be used to join the two substrates together as illustrated in FIG. 13. The bulk silicon thinning step involves a process called electro-chemical etch that forms oxide and stops on the p-n junction interface. This high selectivity ensures the uniformity of the device layer. The p+ layer can be removed by etch, polish, or oxidation, etc. as shown in FIG. 14.

FIG. 15 is a simplified cross section diagram of a complete single-side transistor structure according to one embodiment of the present invention. As depicted, a CMOS structure is completely fabricated with VIAs formed in the device layer, either partial or thru stop on oxide.

FIG. 16 is a simplified cross section diagram of a complete double-side transistor structure according to one embodiment of the present invention. As depicted, a second CMOS structure can be fabricated in a similar fashion as above. The top and bottom CMOS structures are physically far enough from each other that they are electrically isolated, only interconnected by VIAs. An optional dielectric layer can further increase isolation in a more compact structure as depicted in FIG. 17.

FIG. 18 is a simplified cross section diagram illustrating layer structure of a dual active layer device according to one embodiment of the present invention. As depicted, the bottom layer is a memory device layer whereas the top layer is a logic device layer, short-ranged interconnected by local VIAs. Standard metal interconnects layers are fabricated the last to form medium and long range interconnect. Finally a passivation layer is deposited at the top.

FIG. 19 is a simplified cross section diagram illustrating components of layer structure of a dual active layer device according to one embodiment of the present invention. As depicted, the top active device layer is imaging pixel device such as CCD, CMOS, thermal/IR imaging device. The bottom layer is a logic device that can process the pixel information in real time.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A multi-surface transistor device, the device comprising:
a substrate member comprising a surface region;
an insulating layer overlying the surface region of the substrate member;
a first gate structure overlying the insulating layer;
a first gate insulating layer overlying the first gate structure;
an active region overlying the first gate insulating layer, the active region comprising a source region, a channel region, and a drain region;
a second gate insulating layer overlying at least the channel region of the active region;
a patterned second gate structure overlying the channel region of the active region, the patterned gate structure having a first edge region and a second edge region;
a first sidewall spacer formed on the first edge region;
a second sidewall spacer formed on the second edge region; and
a trench isolation structure provided to form a boundary for the active region and provided to form the first gate structure and isolate the first gate structure from at least a second cell region.

2. The device of claim 1 wherein the substrate member comprises single crystal silicon material.

3. The device of claim 1 wherein the first gate insulating layer comprises silicon dioxide.

4. The device of claim 1 wherein the first gate insulating layer comprises silicon oxy nitride.

5. The device of claim 1 wherein the first gate insulating layer comprises a nitride bearing material.

6. The device of claim 1 wherein the channel region has a length of 110 nanometers and less.

7. The device of claim 1 wherein the first gate structure is a blanket layer of polycrystalline silicon material.

8. The device of claim 1 wherein the first gate structure is a blanket layer of deposited polycrystalline silicon material.

9. The device of claim 1 wherein the first gate structure is an in-situ doped blanket layer of deposited polycrystalline silicon material.

10. The device of claim 1 wherein the active region comprises a single crystal silicon bearing material.

11. The device of claim 1 wherein the first side wall spacer and the second sidewall spacers comprise a nitride bearing material.

12. The device of claim 1 wherein the first side wall spacer and the second sidewall spacer comprise an oxide bearing material.

13. The device of claim 1 further comprising an interlayer dielectric layer overlying the second gate structure.

14. The device of claim 1 wherein the channel region comprises a single channel region coupled between the source region and the drain region.

15. The device a claim 1 wherein the channel region comprises a first channel region and a second channel region.

16. The device of claim 1 the first gate structure corresponds to a first MOS transistor structure and the second gate structure corresponds to a second MOS transistor structure, whereupon the first MOS transistor structure is operable independent of the second MOS transistor structure.

17. The device of claim 1 the first gate structure corresponds to a first MOS transistor structure, the first MOS transistor structure comprising a first source region provided within a portion of the source region, a first channel region provided within a portion of the channel region, and a first drain region provided within a portion of the drain region, and the second gate structure corresponds to a second MOS transistor structure, the second MOS transistor structure comprising a second source region provided within a portion of the source region, a second channel region provided within a portion of the channel region, and a second drain region provided within a portion of the drain region, whereupon the first MOS transistor structure is operable independent of the second MOS transistor structure.

18. The device of claim 1 the first gate structure corresponds to a first MOS transistor structure and the second gate structure corresponds to a second MOS transistor structure, whereupon the first MOS transistor structure is operable dependent of the second MOS transistor structure.

19. The device of claim 1 the first gate structure corresponds to a first MOS transistor structure, the first MOS transistor structure comprising a first source region provided within a portion of the source region, a first channel region provided within a portion of the channel region, and a first drain region provided within a portion of the drain region, and the second gate structure corresponds to a second MOS transistor structure, the second MOS transistor structure comprising a second source region provided within a portion of the source region, a second channel region provided within a portion of the channel region, and a second drain region provided within a portion of the drain region, whereupon the first MOS transistor structure is operable dependent of the second MOS transistor structure.

20. A double gated MOS transistor device, the device comprising:
a substrate member comprising a surface region;
an insulating layer overlying the surface region of the substrate member;
a first gate structure overlying the insulating layer;
a first gate insulating layer overlying the first gate structure;
an active region overlying the first gate insulating layer, the active region comprising a source region, a channel region, and a drain region;
a second gate insulating layer overlying at least the channel region of the active region;
a patterned second gate structure overlying the channel region of the active region, the patterned gate structure having a first edge region and a second edge region;
a first sidewall spacer formed on the first edge region;
a second sidewall spacer formed on the second edge region;
an isolation region forming a boundary for the active region provided by a trench isolation structure;
whereupon the trench isolation structure forms the first gate structure and also isolate the first gate structure from at least an adjacent cell region.

21. A method for forming double gated MOS transistor device, the method comprising:
providing a substrate member comprising a surface region;
forming an insulating layer overlying the surface region of the substrate member;
forming a first gate layer overlying the insulating layer;
forming a first gate insulating layer overlying the first gate layer;
forming an active region overlying the first gate insulating layer, the active region comprising a source region, a channel region, and a drain region;
forming a second gate insulating layer overlying at least the channel region of the active region;
forming a second gate layer overlying the second gate insulating layer;
patterning the second gate layer to form a second gate structure overlying the channel region of the active region, the second gate structure having a first edge region and a second edge region;
providing a first sidewall spacer formed on the first edge region and a second sidewall spacer formed on the second edge region; and
forming a trench isolation structure to provide an isolation region formed within a vicinity of a boundary of the active region provided by the trench isolation structure and simultaneously during a portion of the forming of the trench isolation structure forming a first gate structure from the first gate layer to isolate the first gate structure from at least an adjacent cell region; whereupon the first gate structure is self aligned to the active region, including the channel region.
